(19) United States
(12) Patent Application Publication
(10) Pub. No.: US 2025/0095964 A1
(43) Pub. Date: Mar. 20, 2025

(54) METHOD TO CONTROL ETCH PROFILE BY RF PULSING

(71) Applicant: Lam Research Corporation, Fremont, CA (US)

(72) Inventors: Daksh AGARWAL, Sunnyvale, CA (US); Beibei JIANG, Alpharetta, GA (US); Shuang PI, Fremont, CA (US); Chen CHEN, Hayward, CA (US); Taner OZEL, Fremont, CA (US); Qing XU, Fremont, CA (US); Merrett WONG, San Carlos, CA (US); Amit MUKHOPADHYAY, Fremont, CA (US); Akanksha GUPTA, San Jose, CA (US); Taeseok OH, Milpitas, CA (US)

(21) Appl. No.: 18/728,062

(22) PCT Filed: Dec. 19, 2022
(86) PCT No.: PCT/US2022/053400

§ 371 Date: Jul. 10, 2024

Related U.S. Application Data
(60) Provisional application No. 63/299,588, filed on Jan. 14, 2022.

(51) Int. Cl. H01J 37/32; H01L 21/3065

(52) U.S. Cl. CPC H01J 37/32146; H01J 37/32183; H01L 21/3065; H01J 2237/3347

(57) ABSTRACT

A method for performing a plasma etch process is provided. The method initiates with receiving a substrate into a chamber. A high frequency (HF) RF signal is generated, said HF RF signal being pulsed in at least a three-state cycle including a first state, a second state, and a third state. The first state is configured at a first power level; the second state is configured at a second power level less than the first power level; and, the third state is configured at a third power level less than the second power level. The second power level of the HF RF signal being in the range of about 0 W to 3500 W. The HF RF signal is applied to an electrode of the chamber for performing the plasma etch process.

### FIELD

The present embodiments relate to systems and methods for a multistate pulsing regime to break the bow CD vs. mask clogging trade off typically observed in RF plasma etching of features on semiconductor wafers.

### BACKGROUND

A plasma tool includes a radio frequency (RF) generator, a match network, and a plasma reactor. The RF generator is coupled via the match network to the plasma reactor. A wafer is placed within the plasma chamber to be etched.

The RF generator generates an RF signal, which is supplied to the match network. The match network reduces reflected power towards the RF generator and provides an output RF signal to the plasma reactor. The output RF signal is used to etch the wafer. However, sometimes, a different process result than that desired may be achieved with the output RF signal.

A significant challenge for high aspect ratio etch processing is the trade-off between bow critical dimension (CD) control versus capping margin. Currently, the main mechanism used to decrease bow critical dimension (CD) is the use of a more polymerizing chemistry. However, the deposition from this polymerizing chemistry happens more in the top region of the high aspect ratio (HAR) structure (neck region) than in the bow region. This leads to a larger decrease in the neck CD than in the bow CD which leads to capping (clogging of the mask opening) before the desired passivation is achieved in the bow region. Additionally, the deposition from the polymerizing chemistry also happens on top of the mask which makes the mask morphology worse and leads to early onset of capping even with comparable neck CDs. Therefore, current technology employed for bow control falls short of reaching the target while also reducing the capping margin in the process. This trade-off between bow critical dimension (CD) control versus capping margin limits the capabilities of etch processes for achieving desired HAR feature dimensions.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Embodiments of the disclosure provide systems, apparatus, methods and computer programs for a multistate pulsing regime to increase deposition conformality during high aspect ratio etch and break the bow CD vs. capping-neck CD trade off. It should be appreciated that the present embodiments can be implemented in numerous ways, e.g., a process, an apparatus, a system, a device, or a method on a computer readable medium. Several embodiments are described below.

A significant challenge for high aspect ratio etch processing is the trade-off between bow critical dimension (CD) control versus capping margin. Lateral etch, which increases bow CD, is typically prevented by sidewall passivation with polymerized chemistry. This sidewall passivation also deposits near the top of the mask and causes necking and, in some instances, capping or clogging of the mask. Thus, the amount of sidewall passivation that can be provided is limited by the process margin for the capping.

However, in accordance with implementations of the disclosure, the trade-off between bow CD reduction and mask capping can be broken by introducing a multistate pulsing regime, with a high-HF RF power intermediate state. An interim pulsing state increases the deposition conformality on the mask and on the high aspect ratio (HAR) feature. This not only reduces the deposition in the neck region but also increases the deposition in the bottom region which leads to more bow protection (and correspondingly a smaller bow CD) with a larger neck CD compared to passivation with conventional process control knobs.

Additionally, the high density of neutrals in the interim pulse state also consumes the irregularities at the top of the mask leading to improvement in mask morphology. This improvement in mask morphology at the top of the mask further reduces the chance of capping with multistate pulsing as compared to the case without multistate pulsing even with comparable neck CDs.

In some implementations, a method for performing a plasma etch process is provided, including: receiving a substrate into a chamber; generating a high frequency (HF) RF signal, said HF RF signal being pulsed in a three-state cycle including a first state, a second state, and a third state; wherein the first state is configured at a first power level; wherein the second state is configured at a second power level less than the first power level; wherein the third state is configured at a third power level less than the second power level; wherein the second power level of the HF RF signal is in the range of about 0 to 3500 W, wherein the HF RF signal is applied to an electrode of the chamber for performing the plasma etch process.

In some implementations, a duty cycle of the second state is in the range of about 0% to 90%.

In some implementations, the third power level is substantially 0 or close to 0.

In some implementations, the plasma etch process is configured to etch a high aspect ratio (HAR) feature on a substrate, and wherein the second state of the HF RF signal is configured to reduce bowing of sidewalls of the HAR feature and further configured to reduce deposition of passivation in a neck region of the HAR feature.

In some implementations, the method further includes: generating a low frequency (LF) RF signal, said LF RF signal being pulsed in a multi-state cycle including at least a first state, a second state, and a third state of the LF RF signal.

In some implementations, the first state of the LF RF signal is configured at a fourth power level; wherein the second state of the LF RF signal is configured at a fifth power level less than the fourth power level; wherein the third state of the LF RF signal is configured at a sixth power level less than the fifth power level; wherein the fifth power level is in the range 0-6000 W wherein the LF RF signal is applied to the electrode of the chamber.

In some implementations, the LF RF signal is configured to control deposition of passivation on a mask layer of a substrate.

In some implementations, a system for performing a plasma etch process is provided, including: a chamber configured to receive a substrate for processing; a high frequency generator that generates a high frequency (HF) RF signal, said HF RF signal being pulsed in a three-state cycle including a first state, a second state, and a third state; wherein the first state is configured at a first power level; wherein the second state is configured at a second power level less than the first power level; wherein the third state is configured at a third power level less than the second power level; wherein the second power level being in the range of about 0 to 3500 W, wherein the HF RF signal is applied to an electrode of the chamber for performing the plasma etch process.

In some implementations, non-transitory computer readable medium having program instructions embodied thereon that, when executed by at least one processor, cause said at least one processor to execute a method for performing a plasma etch process, said method including: receiving a substrate into a chamber; generating a high frequency (HF) RF signal, said HF RF signal being pulsed in a three-state cycle including a first state, a second state, and a third state; wherein the first state is configured at a first power level; wherein the second state is configured at a second power level less than the first power level; wherein the third state is configured at a third power level less than the second power level; wherein the second power level of the HF RF signal being in the range of about 0 to 3500 W, wherein the HF RF signal is applied to an electrode of the chamber for performing the plasma etch process.

Other aspects will become apparent from the following detailed description, taken in conjunction with the accompanying drawings.

### BRIEF DESCRIPTION OF THE DRAWINGS

The embodiments may best be understood by reference to the following description taken in conjunction with the accompanying drawings.

FIG. 1 is a diagram of an embodiment of a system 100 for performing an etch process, in accordance with implementations of the disclosure.

FIG. 2A is a graph conceptually illustrating the phases of a three state RF pulsing regime, in accordance with implementations of the disclosure.

FIG. 2B is a graph conceptually illustrating the phases of a three state RF pulsing regime, in accordance with implementations of the disclosure.

FIGS. 3A, 3B, and 3C conceptually illustrate cross-sections of etched features undergoing different etch processes, in accordance with implementations of the disclosure.

FIG. 4A is a graph illustrating low frequency RF power versus time for a pulsed low frequency (LF) RF signal (e.g. 400 kHz), in accordance with implementations of the disclosure.

FIG. 4B is a graph depicting LF RF power versus time for a pulsed LF RF signal, in accordance with implementations of the disclosure.

FIGS. 5A and 5B are top view conceptual schematics of a substrate surface illustrating the impact of LF RF power in controlling mask shape, in accordance with implementations of the disclosure.

### DETAILED DESCRIPTION

The following embodiments describe systems and methods for a multistate pulsing regime to increase deposition conformality during high aspect ratio etch and break the bow CD vs. capping-neck CD trade off. It will be apparent that the present embodiments may be practiced without some or all of these specific details. In other instances, well known operations have not been described in detail in order not to unnecessarily obscure the present embodiments.

Multistate pulsing with a high HF RF power in the third state addresses the problem of the trade-off between bow critical dimension (CD) control versus capping margin in two ways. Firstly, it increases the conformality of deposition in the HAR structure, and as a result, produces less deposition in the neck region and more deposition in the bow region. Not only does this passivate the bow at a faster rate, but this also decreases the neck CD reduction. Therefore, more passivation can be achieved before the onset of capping. Secondly, the neutrals generated during the high HF RF power state clean the top of the mask thereby leading to an improvement in mask morphology which further increases the capping margin. This translates to less/no capping for comparable neck CDs in a process which has a high HF RF power intermediate state than otherwise achievable because of better mask morphology.

The extent of passivation can be controlled by controlling the HF RF power in the intermediate state. For more bow CD reduction, HF RF power in the intermediate state can be increased. Alternately, the duration of the intermediate state can also be increased by increasing the pulse width to increase the passivation. These two knobs can be used in conjugation to achieve the desired passivation.

A significant advantage of the presently disclosed multistate pulsing regime is the breaking of the trade-off between bow CD and neck CD-capping. The HF RF power intermediate state leads to more conformal deposition on the HAR structure, which is otherwise very difficult to control in the HAR etch process. This reduces the deposition in the neck region but increases deposition in the bow region. As a result, better bow protection can be achieved when compared to conventional chemistry tuning knobs without causing capping.

A second advantage is that while the multistate pulsing regime improves bow, it also cleans the top of the mask which improves mask morphology. This improved mask morphology reduces the capping risk even for comparable or smaller neck CDs.

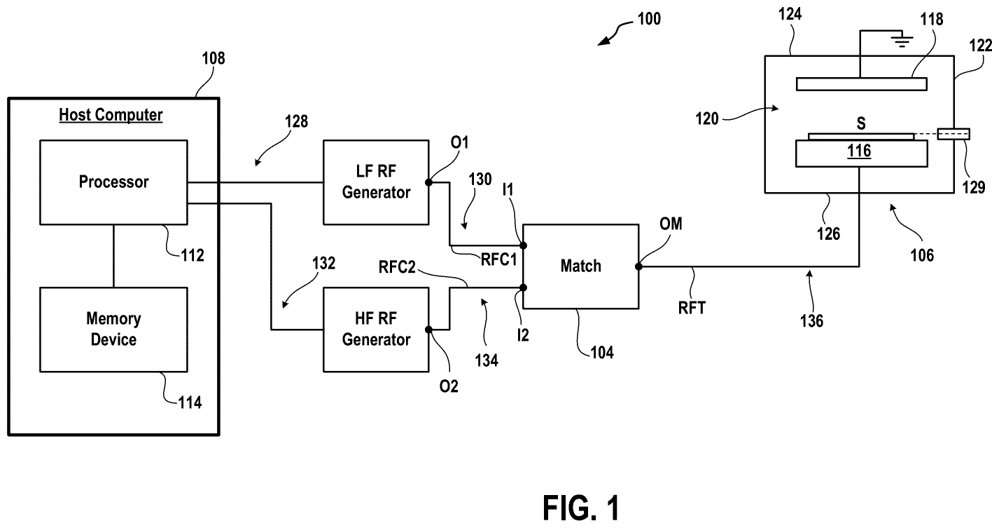

FIG. 1 is a diagram of an embodiment of a system 100 for performing an etch process, in accordance with implementations of the disclosure.

The system 100 includes a high frequency (HF) RF generator, a low frequency (LF) RF generator, a match 104, a plasma chamber 106, and a host computer 108. An illustration of the LF RF generator is an RF generator having a low frequency of operation of 100 kilohertz (kHz), or 400 kHz, or 1 megahertz (MHz), or 2 MHz. An illustration of the HF RF generator is an RF generator having a high frequency of operation of 2 MHz, 13.56 MHz, 27 MHz, 60 MHz, or 120 MHz. To further illustrate, the HF RF generator has a higher frequency than a frequency of operation of the LF RF generator. The LF RF generator is an example of a primary generator and the HF RF generator is an example of a secondary RF generator.

The match 104 is sometimes referred to herein as an impedance matching circuit or an impedance matching network. As an example, the match 104 includes a network of circuit components that are coupled to each other. An example of a circuit component is a resistor, an inductor, or a capacitor.

Examples of the host computer 108 include a desktop computer, a laptop computer, a tablet, a smart phone, and a controller. The host computer 108 includes a processor 112 and a memory device 114. As an example, the processor 112 can be a central processing unit (CPU), a combination of the CPU and a graphical processing unit (GPU), a field programmable gate array (FPGA), an application specific integrated circuit (ASIC), a programmable logic device (PLD), or a microcontroller. Examples of the memory device 114 include a read-only memory (ROM) and a random access memory (RAM). The processor 112 is coupled to the memory device 114.

The plasma chamber 106 includes a substrate support 116, such as an electrostatic chuck (ESC). The plasma chamber 106 further includes an upper electrode 118 that is located above the substrate support 116 to form a gap 120 between the upper electrode 118 and the substrate support 116. A lower electrode, embedded within the substrate support 116, is made from a metal, such as aluminum or an alloy of aluminum. The substrate support 116 is made from the metal and from ceramic, such as aluminum oxide (Al₂O₃). The upper electrode 118 is fabricated from the metal and is coupled to a reference potential, such as a ground potential or a negative potential. An example of the plasma chamber 106 is a capacitively coupled plasma (CCP) chamber.

An example of a substrate S, as used herein, includes a semiconductor wafer having multiple layers. To illustrate, the substrate includes multiple layers that form an integrated circuit, such as an ASIC or a PLD. The processor 112 is coupled to the LF RF generator, the HF RF generator, and the electron microscope 110.

An output O1 of the LF RF generator is coupled to an input I1 of the match 104 via an RF cable RFC1. Also, an output OM of the match 104 is coupled via an RF transmission line RFT to the lower electrode of the substrate support 116. An example of the RF transmission line RFT includes an RF cable that is surrounded by an RF sheath, with an insulator between the RF cable and the RF sheath.

The plasma chamber 106 has a side wall 122, a top wall 124, and a bottom wall 126. The side wall 122 is located between the top wall 124 and the bottom wall 126. The side wall 122 is fitted with the top wall 124 and the bottom wall 126. A slot 129 extends through the side wall 122.

The processor 114 generates a recipe signal 128 and sends the recipe signal 128 to the LF RF generator. The recipe signal 128 includes LF recipe information, such as, a number of states of the parameter of an RF signal 130 to be generated by the LF RF generator, a parameter level for each state of the RF signal 130, a duty cycle of each of the states, and a frequency of the RF signal 130. Similarly, the processor 114 generates a recipe signal 132 and sends the recipe signal 132 to the HF RF generator. The recipe signal 132 includes a number of states of the parameter of an RF signal 102 to be generated by the HF RF generator, a parameter level for each state of the RF signal 102, a duty cycle of each of the states, and a frequency of the RF signal 102.

After receiving the recipe signal 128, the LF RF generator generates the RF signal 130 based on the parameter levels for the number of states received within the recipe signal 128. For example, in some implementations, the RF signal 130 has three states and each of the three states has a corresponding one of the parameter levels received within the recipe signal 128. The RF signal 130 also has the frequency received within the recipe signal 128. Also, after receiving the recipe signal 132, the HF RF generator generates the RF signal 134 having the parameter levels for the number of states received within the recipe signal 132. For example, in some implementations, the RF signal 134 has three states and each state has a corresponding one of the parameter levels received within the recipe signal 132. The RF signal 134 also has the frequency received within the recipe signal 132.

The RF signal 130 is sent from the output O1 via the RF cable RFC1 and the input I1 to the match 104. Also, the RF signal 134 is sent from the output O2 via the RF cable RFC2 and the input I2 to the match 104.

The match 104 receives the RF signals 130 and 134, and matches an impedance of a load coupled to the output OM with an impedance of a source coupled to the inputs I1 and I2. The impedance matching modifies impedances of the RF signals 130 and 134 to output a modified RF signal 136 at the output OM. An example of the load includes the RF transmission line RFT and the plasma chamber 106. An example of the source coupled to the inputs I1 and I2 includes the LF RF generator, the RF cable RFC1, the HF RF generator, and the RF cable RFC2. The modified RF signal 136 is sent from the output OM via the RF transmission line RFT to the lower electrode of the substrate support 116.

When one or more process gases are supplied to the gap 120 within the plasma chamber 106 in addition to the modified RF signal 136, plasma is stricken or maintained within the gap 120 to process the substrate S. Examples of processing the substrate S include depositing a material on the substrate S, etching a layer of the substrate S, cleaning the substrate S, and sputtering the substrate S. Examples of the one or more process gases include an oxygen containing gas, a fluorine containing gas, and a combination thereof. To illustrate, the one or more process gases include carbon and hydrogen, e.g., CHF3. In some implementations, one or more process gases include H2, CF4, NF3, CH2F2, SF6, and/or CH3F. As another illustration, when an amount of the carbon and hydrogen is reduced, a hydrogen gas or nitrogen triflouride (NF3) gas can be used as the one or more process gases.

Upon processing the substrate S for a predetermined amount of time, such as 15 minutes or 20 minutes, the substrate S can be removed from the plasma chamber 106 via the slot 129. As an example, in some implementations, it takes an hour or so for the substrate S to finish processing.

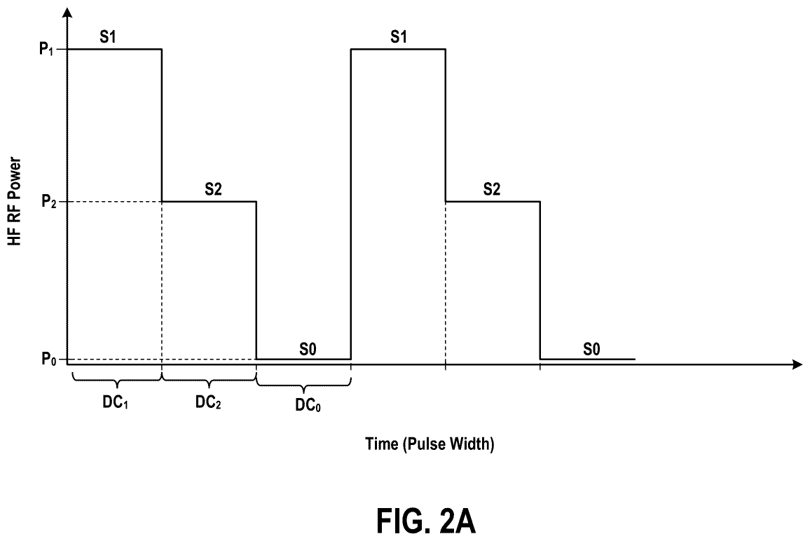

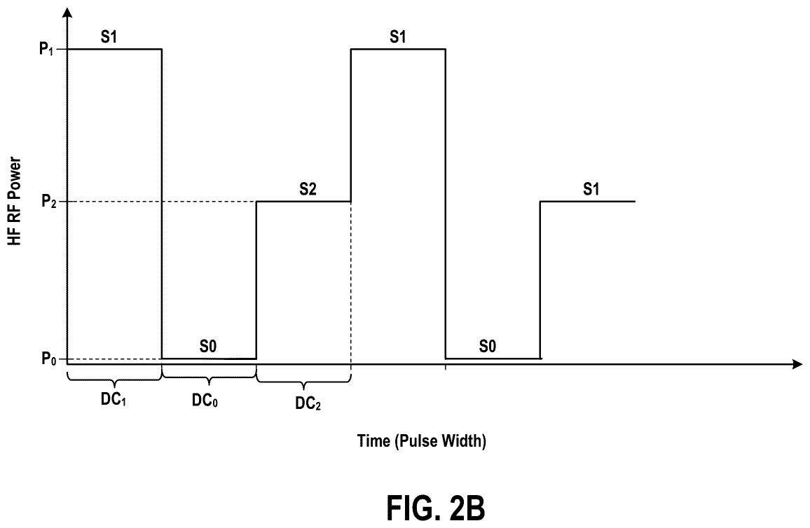

FIG. 2A is a graph conceptually illustrating the phases of a three state RF pulsing regime, in accordance with implementations of the disclosure. In the illustrated graph, RF power versus time is shown, with two cycles of a pulsed high frequency (HF) RF signal shown. In some implementations, the pulsed HF RF signal is that of an RF signal generated by the high frequency RF generator at a frequency in the range of approximately 2 to 100 MHz (e.g. 2 MHz, 13.56 MHz, 27.12 MHz, 40.68 MHz, 60 MHz, etc.). In other implementations, the pulsed RF signal is that of another frequency RF signal used for an etch process.

With continued reference to FIG. 2A, each RF pulsing cycle consists of at least three distinct states. A state S1 is a high-power state having an RF power level P1 and a duty cycle DC1. A state S2 is a mid-power state having an RF power level P2 and a duty cycle DC2. And a state S0 is a low-power state having an RF power level P0 and a duty cycle DC0. The illustrated three-state pulsed RF cycle is in contrast with a two-state pulsed RF signal which employs only a high-power state S1 and a low-power state S0. However, in accordance with implementations of the disclosure, the introduction of the mid-power state S2 as described herein provides significant benefits for breaking the bow CD versus capping margin trade-off.

The three-state pulsed RF signal is tuned, at least in part by tuning parameters including the HF RF power and the pulse width of state S2. Merely as one example for illustration, S1 power could be 1000 W, and the S2 power could be 100 W.

Merely as one example for illustrating the principle, if the S1 duty cycle is 33% of the total pulse width of the RF pulsing cycle, the S2 duty cycle could be 33% of the pulse width. Additionally, the remaining 34% of the pulse width would be state S0 in a three-state pulsed cycle.

Though the specific duty cycles of the states S1, S2, and S0 can vary depending on the specific tuning of the pulsed RF signal for a given etch process, typically S1 is the shortest duty cycle. The duty cycle of S2 can be longer or shorter than the duty cycle of S1, depending on the process and desired outcome. The duty cycle of S0 is typically the longest duty cycle, but in some instances may not be if the duty cycle of S2 is very long. Generally, in some implementations, the duty cycle of S2 is tuned for a given process, with the duty cycle of S1 being fixed, and the duty cycle of S0 being the remaining amount after the duty cycle of S2 has been tuned. In other words, in some implementations, an increase in the duty cycle of S2 causes a corresponding and equivalent reduction in the duty cycle of S0, but does not affect the duty cycle of S1.

In some implementations, the high frequency (HF) RF power in state S2 is in the range of about 0 to 3500 W. In some implementations, the HF RF power in state S2 is in the range of about 1000 W to 3500 W. In some implementations, the HF RF power of state S2 is in the range of about 1000 W to 2000 W.

In some implementations, pulse width (duty cycle) of state S2 is in the range of about 0 to 90% (of the total duration of one pulsed cycle). In some implementations, the pulse width of state S2 is in the range of about 20% to 90%. In some implementations, the pulse width of state S2 is in the range of about 30% to 70%.

FIG. 2B is a graph conceptually illustrating the phases of a three-state RF pulsing regime, in accordance with implementations of the disclosure. In the illustrated graph, RF power versus time is shown, with two cycles of a pulsed RF signal shown. The RF pulse cycle is similar to that of FIG. 2A, except that in the implementation of FIG. 2B, the state S0 directly follows state S1 in the RF pulse cycle, and state S2 directly follows state S0. By contrast, in the implementation of FIG. 2A, the order of states S2 and S0 are switched, so that S2 directly follows S1, and S0 directly follows S2.

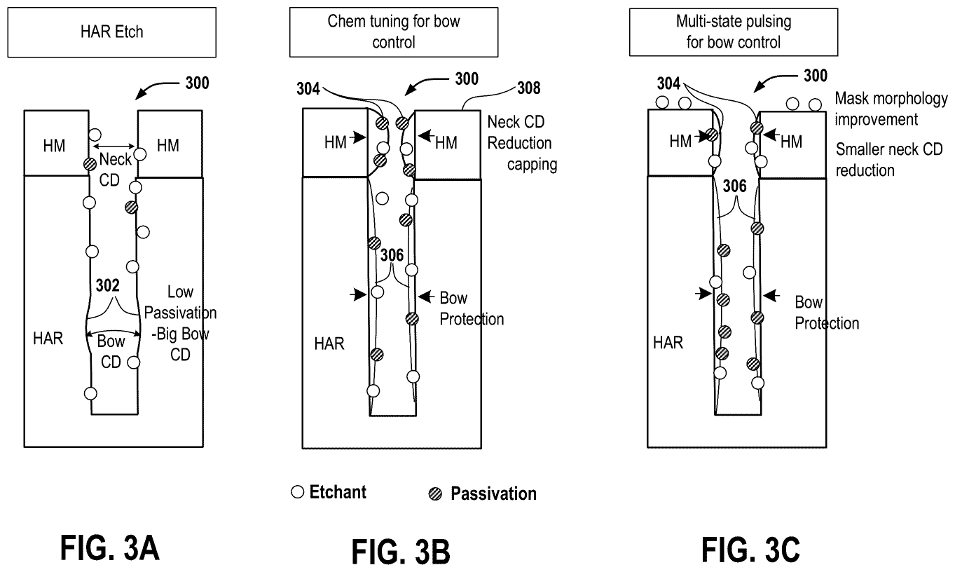

FIGS. 3A, 3B, and 3C conceptually illustrate cross-sections of etched features undergoing different etch processes, in accordance with implementations of the disclosure.

FIG. 3A depicts a conceptual cross-section of an etched feature 300 according to a conventional high-aspect ratio (HAR) etch process. In a typical HAR etch process, a combination of etchants and passivants are utilized. However, as etching proceeds to deeper and deeper depths in a HAR feature, there is a tendency to develop bowing of the sidewalls 302 in the feature 300, as ion scattering is more pronounced in deeper features. This negatively impacts the directionality (anisotropy) of the etch process, producing some etching of the sidewalls causing profile bowing and increasing the bow CD. A high bow CD can lead to device failure due to shorting.

FIG. 3B depicts a conceptual cross-section of the etched feature 300 according to a HAR etch process with chemistry tuning applied for bow control. To combat the problem of high bow CD as identified above, passivating chemistries are applied, which produce deposition of passivation 306 (e.g. polymers) along the sidewalls of the feature, thereby protecting against bowing of the feature. However, such passivating chemistries also deposit on top of the mask layer 308 and tend to deposit more passivation 304 in the top/neck region of the feature. This reduces the neck CD, and there is a risk of capping of the feature when deposition in the neck region clogs and completely closes the hole. Hence, when attempting to reduce bowing of the feature profile, there is a trade-off with the potential for capping of the feature. The risk of capping sets limits on how much passivation chemistry can be applied to improve the bow profile.

FIG. 3C depicts a conceptual cross-section of the etched feature 300 according to a HAR etch process with chemistry tuning applied for bow control and three-state RF pulsing as described above, in accordance with implementations of the disclosure. As shown, the use of multi-state pulsing including HF RF power and pulse width allows for more conformal deposition of the passivation chemistry. There is deposition of passivation 306 along the sidewalls which reduces the bow CD as before, but there is also a reduction in deposition of passivation 304 in the neck/top region of the feature 300, opening the neck CD and improving the capping margin. Thus, the typical trade-off is broken as bow CD is decreased while improving the capping margin.

Without being bound by any particular theory of operation, it is nonetheless believed that the various states S1, S2 and S0 provide different activities which combine to enable breaking the bow control versus capping margin trade-off in HAR etch. State S1 is a high power state providing high energy ions provides etching at high aspect ratios at the etch front. The high energy ions move vertically, and very deep because of their high energy. However, these high energy ions also remove passivation from the top of the film, and thus S1 is not desirable for the entire RF cycle.

State S0 is a very low power state (e.g. in some implementations, 0 or close to 0 power; in some implementations, less than a few hundred Watts; in some implementations, less than 500 W; in some implementations, less than 1000 W; etc.), which allows deposition reactions to occur. Etch reactions are very fast, but deposition reactions are usually slower, and hence S0 gives depositing species enough time to attach to sidewalls of the feature being etched. However, the problem is that at lower aspect ratios (shallower depth), there is more deposition which causes capping and decreases the amount of high energy ions in next step that can penetrate and etch.

State S2 provides higher power than S0, but not so high that would cause removal of passivation from the mid-stack. S2 provides enough power to remove deposited species from low AR regions, but not enough to remove passivation from the middle region of the hole. S2 provides a high HF RF power state generating neutrals and ions in sufficient quantities to remove the unwanted deposition at the top of the mask that causes capping. So this improves the capping margin while in deeper regions, also providing passivation along the sidewalls of the feature.

In some etch processes, a pulsed HF RF signal such as has been described is applied alone. However, in other etch processes, a pulsed low frequency (LF) RF signal is also provided. For example, in some implementations, an etch process is configured to utilize a pulsed HF RF signal alone, whereas in other implementations, such an etch process utilizes both a pulsed HF RF signal as well as a pulsed LF RF signal.

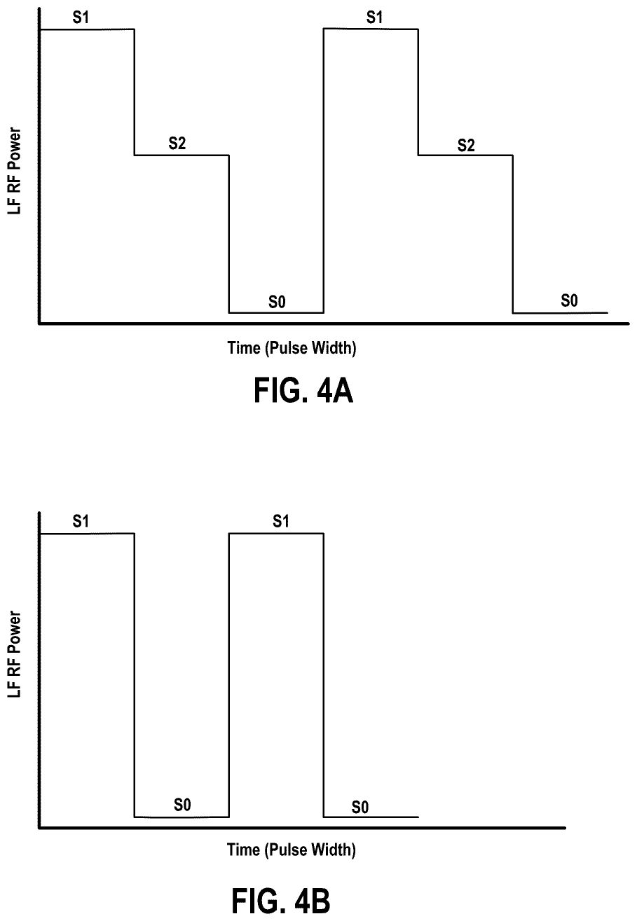

FIG. 4A is a graph illustrating low frequency RF power versus time for a pulsed low frequency (LF) RF signal (e.g. 400 kHz), in accordance with implementations of the disclosure. In some implementations, the pulsed LF RF signal is generated by the LF RF generator as described above.

With continued reference to FIG. 4A, each LF RF pulsing cycle consists of three distinct states which are synchronized in time with, and have the same duty cycles as, the three states of the HF RF signal described above. State S1 of the LF RF signal is a high-power state having the same duty cycle DC1 as S1 of the HF RF signal. State S2 of the LF RF signal is a mid-power state having the same duty cycle DC2 as S2 of the HF RF signal. And state S0 of the LF RF signal is a low-power state (in some implementations, zero power) having the same duty cycle DC0 as S0 of the HF RF signal.

The three-state pulsed LF RF signal is tuned, at least in part by tuning parameters including LF RF power. Merely as one example for illustration, if S1 power is 1000 W, the S2 power can be 500 W.

In some implementations, the LF RF power is in the range of about 0 to 20000 W. In some implementations, LF RF power is in the range of about 4000 W to 16000 W. In some implementations, the LF RF power is in the range of about 6000 W to 12000 W.

Adding low frequency power to the multistate pulsing regime helps provide mask shape control for certain processes. Extending this trend further also provides bow control which helps break the trade off between bow CD and capping/neck CD.

Some processes do not require a LF RF power in S2 In such implementations the LF RF power is set to 0. FIG. 4B is a graph depicting LF RF power versus time for a pulsed LF RF signal, in accordance with implementations of the disclosure. As shown in the illustrated graph, the result of setting the LF RF power to zero is that the state S0 for LF is essentially extended to include the duty cycle of state S2 previously described. This yields a two-state pulsed LF RF signal as shown, with S1 of the LF RF signal synchronized with the S1 of the HF RF signal, and the S0 of the LF RF signal synchronized to the combined duty cycles of the S2 and S0 states of the HF RF signal.

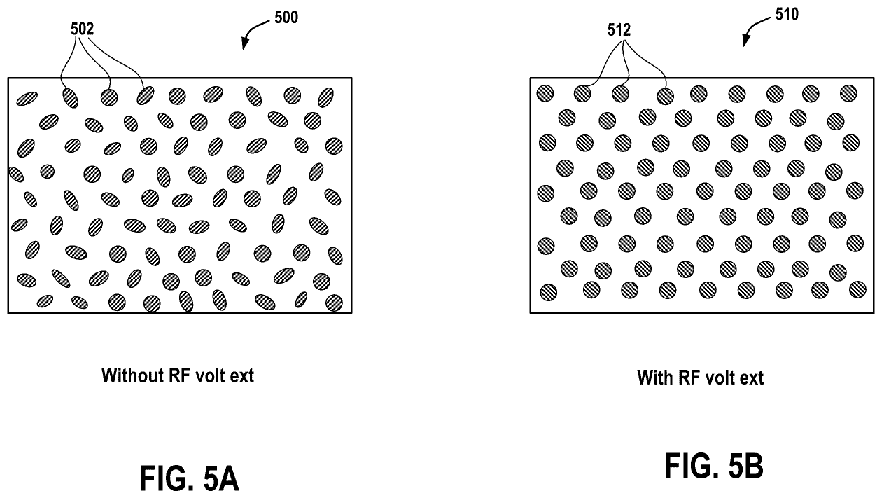

FIGS. 5A and 5B are top view conceptual schematics of a substrate surface illustrating the impact of LF RF power in controlling mask shape, in accordance with implementations of the disclosure.

FIG. 5A illustrates a top view 500 of a portion of a substrate after etch processing without LF RF power. The original hole shape is circular, but as can be seen, the shape of the etched holes 502 after etch processing is inconsistent and often non-circular. Some holes are elongated along a given axis, and the sizing of the holes is inconsistent. This is attributable to the existence of uncontrolled deposition on the mask due to the heavily polymerizing chemistry that is applied for passivation purposes. The uncontrolled deposition causes the holes to be misshapen and lose their circularity. The non-uniform and non-circular holes cause inconsistent sidewall profiles in the etched features, and a worsening of the bow CD due to ion deflection effects.

FIG. 5B illustrates a top view 510 of a portion of a substrate after etch processing with LF RF power. As seen, the shape of the holes 512 is improved, both in terms of uniformity and maintenance of their circular shape. The application of power in the LF RF signal is thus controlling the unwanted deposition.

In some implementations, LF RF power is not needed and therefore set to zero, which as described above, results in a two-state LF RF signal. However, in other process regimes, LF RF power is applied to control deposition on the mask and improve the shape and consistency of holes.

It will be appreciated that during a tuning process, the HF RF power, duty cycle of S2, and possibly the LF RF power are adjusted and tuned to suitable values for a given process. The RF power and the duty cycle of the S2 state of the HF RF signal, and optionally the LF RF power (for the S2 state of the LF RF signal), provide knobs applied to achieve reduction in bow and reduction in necking at the same time, breaking this typical tradeoff. Such multi-state pulsing allows for more conformal deposition along the sidewalls to reduce bow CD while also depositing less at the top of the mask which improves the capping margin.

In some implementations, the above-described parameters of HF RF power, duty cycle, and LF RF power can be adjustable via a user interface provided through a computer or controller, which may be an example of the host computer 108 of FIG. 1. In some implementations, such a user interface provides fields for entry of values of these parameters, and/or selectable icons enabling stepwise adjustment of the values, or other types of interface mechanisms for setting the parameters. In some implementations, predefined values and/or predefined ranges for the parameters of HF RF power, duty cycle, and/or LF RF power, are provided through the user interface. In some implementations, such predefined values or ranges are automatically generated in response to selection or input of other settings relating to the process, such as the type of process, the inclusion or exclusion of a LF RF signal, etc. In some implementations, a predefined value is provided as a default value which can be tuned or adjusted as desired by the user.

Embodiments described herein may be practiced with various computer system configurations including hand-held hardware units, microprocessor systems, microprocessor-based or programmable consumer electronics, minicomputers, mainframe computers and the like. The embodiments can also be practiced in distributed computing environments where tasks are performed by remote processing hardware units that are linked through a network.

In some embodiments, a controller is part of a system, which may be part of the above-described examples. Such systems include semiconductor processing equipment, including a processing tool or tools, chamber or chambers, a platform or platforms for processing, and/or specific processing components (a wafer pedestal, a gas flow system, etc.). These systems are integrated with electronics for controlling their operation before, during, and after processing of a semiconductor wafer or substrate. The electronics is referred to as the “controller,” which may control various components or subparts of the system or systems. The controller, depending on the processing requirements and/or the type of system, is programmed to control any of the processes disclosed herein, including the delivery of process gases, temperature settings (e.g., heating and/or cooling), pressure settings, vacuum settings, power settings, RF generator settings, RF matching circuit settings, frequency settings, flow rate settings, fluid delivery settings, positional and operation settings, wafer transfers into and out of a tool and other transfer tools and/or load locks coupled to or interfaced with a system.

Broadly speaking, in a variety of embodiments, the controller is defined as electronics having various integrated circuits, logic, memory, and/or software that receive instructions, issue instructions, control operation, enable cleaning operations, enable endpoint measurements, and the like. The integrated circuits include chips in the form of firmware that store program instructions, digital signal processors (DSPs), chips defined as ASICs, PLDs, and/or one or more microprocessors, or microcontrollers that execute program instructions (e.g., software). The program instructions are instructions communicated to the controller in the form of various individual settings (or program files), defining the parameters, the factors, the variables, etc., for carrying out a particular process on or for a semiconductor wafer or to a system. The program instructions are, in some embodiments, a part of a recipe defined by process engineers to accomplish one or more processing steps during the fabrication of one or more layers, materials, metals, oxides, silicon, silicon dioxide, surfaces, circuits, and/or dies of a wafer.

The controller, in some embodiments, is a part of or coupled to a computer that is integrated with, coupled to the system, otherwise networked to the system, or a combination thereof. For example, the controller is in a “cloud” or all or a part of a fab host computer system, which allows for remote access of the wafer processing. The computer enables remote access to the system to monitor current progress of fabrication operations, examines a history of past fabrication operations, examines trends or performance metrics from a plurality of fabrication operations, to change parameters of current processing, to set processing steps to follow a current processing, or to start a new process.

In some embodiments, a remote computer (e.g. a server) provides process recipes to a system over a network, which includes a local network or the Internet. The remote computer includes a user interface that enables entry or programming of parameters and/or settings, which are then communicated to the system from the remote computer. In some examples, the controller receives instructions in the form of data, which specify the parameters, factors, and/or variables for each of the processing steps to be performed during one or more operations. It should be understood that the parameters, factors, and/or variables are specific to the type of process to be performed and the type of tool that the controller is configured to interface with or control. Thus as described above, the controller is distributed, such as by including one or more discrete controllers that are networked together and working towards a common purpose, such as the processes and controls described herein. An example of a distributed controller for such purposes includes one or more integrated circuits on a chamber in communication with one or more integrated circuits located remotely (such as at the platform level or as part of a remote computer) that combine to control a process on the chamber.

Without limitation, in various embodiments, example systems to which the methods are applied include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that is associated or used in the fabrication and/or manufacturing of semiconductor wafers.

It is further noted that in some embodiments, the above-described operations apply to several types of plasma chambers, e.g., a plasma chamber including an inductively coupled plasma (ICP) reactor, a transformer coupled plasma chamber, conductor tools, dielectric tools, a plasma chamber including an electron cyclotron resonance (ECR) reactor, etc. For example, one or more RF generators are coupled to an inductor within the ICP reactor. Examples of a shape of the inductor include a solenoid, a dome-shaped coil, a flat-shaped coil, etc.

As noted above, depending on the process step or steps to be performed by the tool, the host computer communicates with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

With the above embodiments in mind, it should be understood that some of the embodiments employ various computer-implemented operations involving data stored in computer systems. These operations are those physically manipulating physical quantities. Any of the operations described herein that form part of the embodiments are useful machine operations.

Some of the embodiments also relate to a hardware unit or an apparatus for performing these operations. The apparatus is specially constructed for a special purpose computer. When defined as a special purpose computer, the computer performs other processing, program execution or routines that are not part of the special purpose, while still being capable of operating for the special purpose.

In some embodiments, the operations may be processed by a computer selectively activated or configured by one or more computer programs stored in a computer memory, cache, or obtained over the computer network. When data is obtained over the computer network, the data may be processed by other computers on the computer network, e.g., a cloud of computing resources.

One or more embodiments can also be fabricated as computer-readable code on a non-transitory computer-readable medium. The non-transitory computer-readable medium is any data storage hardware unit, e.g., a memory device, etc., that stores data, which is thereafter be read by a computer system. Examples of the non-transitory computer-readable medium include hard drives, network attached storage (NAS), ROM, RAM, compact disc-ROMs (CD-ROMs), CD-recordables (CD-Rs), CD-rewritables (CD-RWs), magnetic tapes and other optical and non-optical data storage hardware units. In some embodiments, the non-transitory computer-readable medium includes a computer-readable tangible medium distributed over a network-coupled computer system so that the computer-readable code is stored and executed in a distributed fashion.

Although the method operations above were described in a specific order, it should be understood that in various embodiments, other housekeeping operations are performed in between operations, or the method operations are adjusted so that they occur at slightly different times, or are distributed in a system which allows the occurrence of the method operations at various intervals, or are performed in a different order than that described above.

It should further be noted that in an embodiment, one or more features from any embodiment, described above, are combined with one or more features of any other embodiment, also described above, without departing from a scope described in various embodiments described in the present disclosure.

Although the foregoing embodiments have been described in some detail for purposes of clarity of understanding, it will be apparent that certain changes and modifications can be practiced within the scope of appended claims. Accordingly, the present embodiments are to be considered as illustrative and not restrictive, and the embodiments are not to be limited to the details given herein.

1. A method for performing a plasma etch process, comprising:
receiving a substrate into a chamber;
generating a high frequency (HF) RF signal, said HF RF signal being pulsed in a three-state cycle including a first state, a second state, and a third state;
wherein the first state is configured at a first power level;
wherein the second state is configured at a second power level less than the first power level;
wherein the third state is configured at a third power level less than the second power level;
wherein the second power level of the HF RF signal is in the range of about 0 to 3500 W,
wherein the HF RF signal is applied to an electrode of the chamber for performing the plasma etch process.

2. The method of claim 1, wherein a duty cycle of the second state of the HF RF signal, is in the range of about 0% to 90%.

3. The method of claim 1, wherein the third power level is substantially 0 or close to 0.

4. The method of claim 1, wherein the plasma etch process is configured to etch a high aspect ratio (HAR) feature on a substrate, and wherein the second state of the HF RF signal is configured to reduce bowing of sidewalls of the HAR feature and further configured to reduce deposition of passivation in a neck region of the HAR feature.

5. The method of claim 1, further comprising:
generating a low frequency (LF) RF signal, said LF RF signal being pulsed in a multi-state cycle including at least a first state, a second state, and a third state of the LF RF signal.

6. The method of claim 5,
wherein the first state of the LF RF signal is configured at a fourth power level;
wherein the second state of the LF RF signal is configured at a fifth power level less than the fourth power level;
wherein the third state of the LF RF signal is configured at a sixth power level less than the fifth power level;
wherein the fifth power level is in the range of about 0 to 20000 W;
wherein the LF RF signal is applied to the electrode of the chamber.

7. The method of claim 6, wherein the LF RF signal is configured to control deposition of passivation on a mask layer of a substrate.

8. A system for performing a plasma etch process, comprising:
a chamber configured to receive a substrate for processing;
a high frequency generator that generates a high frequency (HF) RF signal, said HF RF signal being pulsed in a three-state cycle including a first state, a second state, and a third state;
wherein the first state is configured at a first power level;
wherein the second state is configured at a second power level less than the first power level;
wherein the third state is configured at a third power level less than the second power level;
wherein the second power level is in the range of about 0 W to 3500 W,
wherein the HF RF signal is applied to an electrode of the chamber for performing the plasma etch process.

9. The system of claim 8, wherein a duty cycle of the second state is in the range of about 0% to 90%.

10. The system of claim 8, wherein the third power level is substantially 0 or close to 0.

11. The system of claim 8, wherein the plasma etch process is configured to etch a high aspect ratio (HAR) feature on a substrate, and wherein the second state of the HF RF signal is configured to reduce bowing of sidewalls of the HAR feature and further configured to reduce deposition of passivation in a neck region of the HAR feature.

12. The system of claim 8, further comprising:
a low frequency generator that generates a low frequency (LF) RF signal, said LF RF signal being pulsed in a three-state cycle including a first state, a second state, and a third state of the LF RF signal.

13. The system of claim 12,
wherein the first state of the LF RF signal is configured at a fourth power level;
wherein the second state of the LF RF signal is configured at a fifth power level less than the fourth power level;
wherein the third state of the LF RF signal is configured at a sixth power level less than the fifth power level;
wherein the fifth power level is in the range of about 0 to 20000 W;
wherein the LF RF signal is applied to the electrode of the chamber.

14. The system of claim 13, wherein the LF RF signal is configured to control deposition of passivation on a mask layer of a substrate.

15. A non-transitory computer readable medium having program instructions embodied thereon that, when executed by at least one processor, cause said at least one processor to execute a method for performing a plasma etch process, said method comprising:
receiving a substrate into a chamber;
generating a high frequency (HF) RF signal, said HF RF signal being pulsed in a three-state cycle including a first state, a second state, and a third state;
wherein the first state is configured at a first power level;
wherein the second state is configured at a second power level less than the first power level;
wherein the third state is configured at a third power level less than the second power level;
wherein the second power level of the HF RF signal is in the range of about 0 to 3500 W,
wherein the HF RF signal is applied to an electrode of the chamber for performing the plasma etch process.

16. The non-transitory computer readable medium of claim 15, wherein a duty cycle of the second state is in the range of about 0 to 90%.

17. The non-transitory computer readable medium of claim 15, wherein the third power level is a substantially zero power level.

18. The non-transitory computer readable medium of claim 15, wherein the plasma etch process is configured to etch a high aspect ratio (HAR) feature on a substrate, and wherein the second state of the HF RF signal is configured to reduce bowing of sidewalls of the HAR feature and further configured to reduce deposition of passivation in a neck region of the HAR feature.

19. The non-transitory computer readable medium of claim 15, wherein the method further comprises:
generating a low frequency (LF) RF signal, said LF RF signal being pulsed in a three-state cycle including a first state, a second state, and a third state of the LF RF signal.

20. The non-transitory computer readable medium of claim 19,
wherein the first state of the LF RF signal is configured at a fourth power level;
wherein the second state of the LF RF signal is configured at a fifth power level less than the fourth power level;
wherein the third state of the LF RF signal is configured at a sixth power level less than the fifth power level;
wherein the fifth power level of the LF RF signal, is in the range of about 0 to 20000 W;
wherein the LF RF signal is applied to the electrode of the chamber.
